(19) United States
(12) Patent Application Publication
(10) Pub. No.: US 2005/0095748 A1
(43) Pub. Date: May 5, 2005

(54) Method for the selective surface treatment of planar workpieces

(76) Inventor: Jurgen Schulz-Harder, Lauf (DE)

Correspondence Address: Stewart L Gitler;Hoffman Wasson & Gitler, 2461 South Clark Street, Suite 522, Arlington, VA, 22202, US

(21) Appl. No.: 10/493,214

(22) PCT Filed: Oct. 11, 2002
(86) PCT No.: PCT/DE02/03836

(30) Foreign Application Priority Data
Nov. 7, 2001 (DE) 101 54 316.6

(51) Int. Cl. H01L 21/50; H01L 21/44; H01L 23/053

(52) U.S. Cl. 438/107; 257/700

(57) ABSTRACT

The invention relates to a method for the selective surface treatment of a planar workpiece, whereby, on at least one of two metallic surface sides, two similar workpieces are detachably connected to eah other at least in a partial region, on teh first surface side thereof, such as to be sealed to the outside.

### BACKGROUND OF THE INVENTION

The invention relates to a process for the selective surface treatment of board-shaped components.

Known in the art is the manufacture of printed circuit boards for electrical and electronic circuits using a board-shaped base material, which in the simplest case consists of an insulating layer that is provided on its two surfaces with a metal layer, for example, with a copper layer. The latter is then structured with known masking and etching technology, so that the required strip conductors, connections, contact surfaces, etc. are retained.

Also known in the art is the manufacture of so-called DCB substrates, which consist essentially of a ceramic layer, for example, a layer of aluminum oxide ceramic, which is provided on its two surfaces with metallization in the form of a metal or copper foil, which then is structured by means of the masking and etching technology. The metal or copper foil is applied with an active soldering process or the known direct bonding process, which is described in US-PS 37 44 120 or DE-PS 23 19 854.

In many cases with board-shaped components with metallic surfaces, for example, printed circuit boards or substrates, it is also necessary, preferably after the structuring of the metallizations, to carry out selective surface treatment, which in the simplest case means that on only one of the two surfaces of the component, at least one metallic layer or several metallic layers are applied one after the other, for example a metal surface of copper is followed by a layer of nickel and on top of that possibly a further layer of gold, e.g. for producing the best possible electric contact or a strip conductor (also for high-frequency circuits) with the lowest possible resistance.

An object of the invention is to present a process that enables the selective surface treatment of board-shaped components with especially simple means.

### SUMMARY OF THE INVENTION

The process according to the invention enables the selective surface treatment in an especially simple manner, without complex processing steps and without the use of additional production aids for covering or masking such surfaces on which the surface treatment should not take place.

“Components” according to the present invention are, in general, board-shaped components with a metallic surface on two opposing surface sides, but preferably printed circuit boards.

“Surface treatment” according to the invention is in particular the application of at least one metallic layer, for example by means of galvanic and/or chemical plating.

### BRIEF DESCRIPTION OF THE DRAWINGS

The invention is described in more detail below based on the drawings and sample embodiments:

FIG. 1 shows a schematic representation in cross section of a DCB single substrate manufactured using the process according to the invention;

FIG. 2 shows a schematic representation in top view of a DCB multiple substrate manufactured using the process according to the invention;

FIG. 3 shows, in different positions, process steps for the manufacture of the substrate in FIG. 1; and

FIG. 4 shows a simplified representation in cross section of a vacuum base plate for use in the process in FIG. 3.

### DETAILED DESCRIPTION OF THE INVENTION

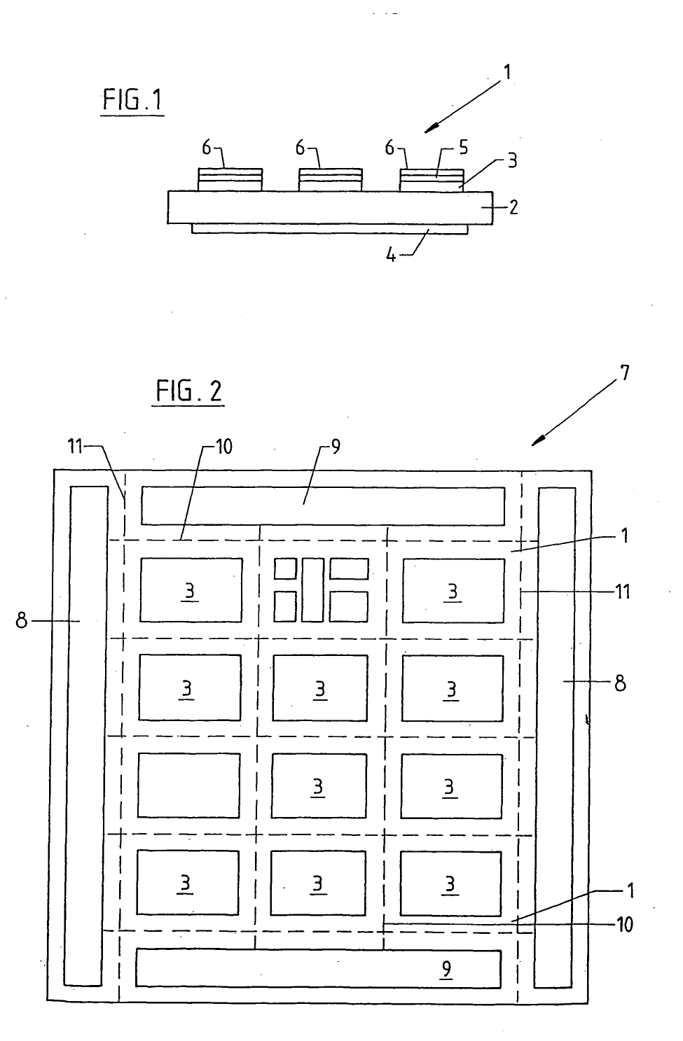

In the drawings, 1 generally designates a DCB single substrate, which includes of a ceramic layer 2 (for example of an aluminum oxide ceramic), a metallization 3 provided on the top side of the ceramic layer 2 and a metallization 4 provided on the bottom side of the ceramic layer 2. Both metallizations 3 and 4 are formed by a copper foil, which is connected on the surface with the ceramic layer 2 by means DCB technology. The metallization 3 is structured so that it forms a plurality of electrically separate strip conductors and/or contact surfaces and/or connections of an electric circuit, which accommodates electric components not depicted that are connected with the contact surfaces or strip conductors. On the top side facing away from the ceramic layer 2 the structured metallization 3 is surface-treated, namely in the manner that by means of chemical plating a nickel layer 5 and on top of this a gold layer 6 is applied, the thicknesses of which however are exaggerated in the depiction in FIG. 1.

The bottom metallization 4 of the DCB single substrate 1 in the depicted embodiment is structured so that this metallization ends at a distance from the edge of the square or rectangular ceramic layer 2. One surface treatment does not have the metallization 4.

The DCB single substrate is produced in a multiple printed panel, i.e. a DCB multiple substrate 7 is manufactured according to FIG. 2 with a plurality of single substrates 1 in rows and columns parallel to the edges, i.e. is structured corresponding to these single substrates 1 on the top and bottom of the ceramic layer of the DCB multiple substrate. On the top forming the surface-treated metallization 3 of the later single substrate 1, the DCB multiple substrate 7 is provided along the edges with additional metal edges or studs 8 and 9 formed by structuring of the respective copper foil to prevent unwanted breaking of the multiple substrate 7 into the single substrates 1 after etching or lasering of the multiple substrate 7, i.e. after placing the break lines 10 between the single substrates 1, namely during further handling of the multiple substrate 7, for example when equipping the single substrates with the electric components, etc. Such metallized metal studs 8 and 9 or metallized edge areas, which prevent unwanted breaking of the multiple substrate 7, are described e.g. in DE 43 19 944 A1.

The surface treatment of the metallizations 3 takes place by a corresponding treatment of the multiple substrate 7 and in any case before separating the multiple substrate 7 into the single substrates 1.

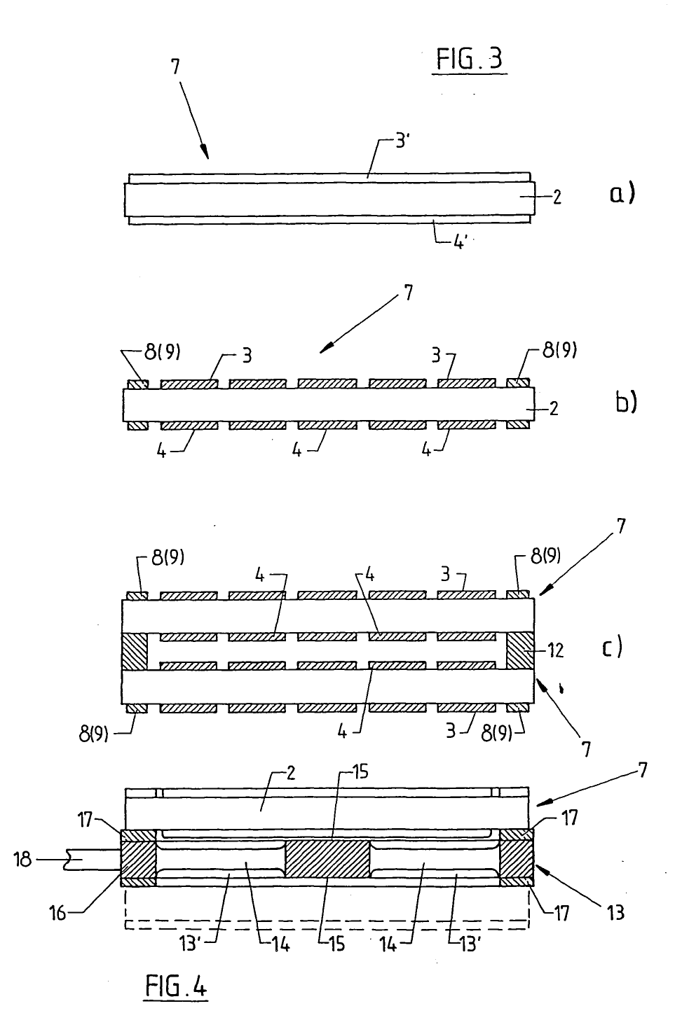

FIG. 3 shows a schematic depiction of various steps for manufacturing the multiple substrate 7 with the selective surface treatment only of the metallizations 3, but not of the metallizations 4.

First, the copper foils 3′ and 4′ forming the metallizations 3 and 4 are applied corresponding to position a) by means of DCB technology to both surfaces of the ceramic layer 2 of the multiple substrate 7. In further processing steps, the copper foils 3′ and 4′ are structured for example by means of the usual masking and etching technology, in order to form the metallizations 3 and 4 of the single substrates 1 corresponding to position b) and at the same time also the metal (copper) studs 8 and 9 along the edges of the multiple substrate 7 on the top of the multiple substrate 7 or the ceramic layer 2. Such metal or copper studs are missing on the bottom of the ceramic layer 2 with the structured metallizations 4 of the single substrates 1.

As FIG. 2 shows, the studs 8 extend over the entire length of the respective edge of the multiple substrate 7, while the studs 9 end at a certain distance from the studs 8, so that in the space formed between the stud 8 and 9 a break line 10 can also be placed parallel to the adjacent stud 8 for example by means of lasering, namely such that this break line 11 extends over the entire width of the multiple substrate 7.

The structuring of the copper foils 3′ and 4′ is followed in a further processing step by the selective surface treatment only of the metallizations 3, but not of the metallizations 4. For this purpose, two multiple substrates 7 are connected with each other tightly but detachably by means of a connecting element 12 with their bottom side accommodating the metallizations 4, namely such that the metallizations 4 are fully covered toward the outside by the connecting element 12. In the depicted embodiment the connecting element 12 has a frame-like design and extends along the edge of the bottom of the multiple substrate 7, namely where the outer metal studs 8 and 9 are located on the top of the respective multiple substrate 7. The connecting element 12 is connected tightly but detachably with the bottoms of the two multiple substrates 7 in a suitable manner, for example by means of a sealing or connecting mass, which makes it possible to detach the multiple substrate 7 from the connecting element 12.

The fact that the metal studs 8 and 9 are missing on the bottom of the multiple substrate 7 on the edge and especially on the transitions between the adjacent metal studs 8 and 9 achieves a full-surface and tight connection between the bottom of the ceramic layer 2 of each multiple substrate 7 and a connecting element 12. The metallizations 4, for which no surface treatment is provided, are therefore located in the space enclosed tightly by the connecting element 12 and the ceramic layers 2 of the two multiple substrates 7, as depicted in position c) of FIG. 3, so that the subsequent surface treatment takes place only on the exposed metallizations 3. In principle, a selective surface treatment of only the metallizations 3 and of the metal studs 8 and 9 would be conceivable by masking the metallizations 4 on the bottom accordingly before the surface treatment. However, the advantage of the process described above over such a procedure is, for example, that the application of additional masking before the selective surface treatment and the removal of this masking after the selective surface treatment and the ensuing additional costs for material and disposal are eliminated; in addition, there are no soiled baths due to the components or coating required for masking in connection with the surface treatment.

It was assumed above that for the selective surface treatment of the metallizations 3, the two multiple substrates 7 are connected with each other by means of the frame-like connecting element 12, using an adhesive and sealing mass. FIG. 4 shows a simplified depiction of a vacuum base plate 13, which can be used for connecting two multiple substrates 7 on their bottom sides during the selective surface treatment of the metallizations 3. The plate 13, the edge dimensions of which correspond to the edge dimensions of the multiple substrate 7 or of the ceramic layer 2 of this multiple substrate, in the depicted embodiment is symmetrical to a middle plane extending parallel to the surfaces of this plate 13, namely with several chambers 13′, which are open toward the two surfaces, and with several studs 14 between the chambers 13′. The studs 14 are designed in partial areas with a low height and in partial areas with a greater height and form in these partial areas of greater height contact or support surfaces 15 for the bottom of the two multiple substrates 7, which are connected with each other by means of the base plate 13. By means of the narrower design of the studs 14 in partial areas the chambers 13′ are connected with each other. Along the edge, the base plate 13 forms a self-contained frame section 16, on which a wraparound seal 17 is located on the top and on the bottom along the edge of the base plate 13. On the frame section 16 there is furthermore at least one connector 18 provided with a shut-off valve and which leads into one of the chambers 13′ and which can be connected or is connected to a vacuum source not depicted.

For the selective surface treatment, the two multiple substrates 7 are placed with their bottom on one side of the vacuum base plate 13, so that the wraparound seal 17 there bears against the bottom of the ceramic layer 2 of a multiple substrate 7, namely along the edge of this multiple substrate where the metal studs 8 and 9 are located on the top. By applying a vacuum to the base plate 13 or the chambers 13′ enclosed by the ceramic layers 2 by means of the connector 18, the multiple substrates 7 are fixed on the base plate 13, so that for example after closing the valve of the connector 18, the selective surface treatment of the multiple substrates 7 on the metallizations 3 can then take place.

In principle it is of course also possible to maintain the vacuum connection to the base plate 13 during the selective surface treatment. The shut-off of the connection 18 after evacuation of the chambers 13′ and before the selective surface treatment ensures, however, that in the event of a faulty seal between the single substrates 7 and the base plate 13, no medium used for the surface treatment can enter the vacuum source.

It was assumed above that the process achieves a selective surface treatment of metallizations on DCB substrates. Of course, the process is also suitable for the selective surface treatment of metallizations of other substrates, which for example can be used as printed circuit boards for electric circuits, e.g. of substrates that have an insulating layer made of ceramic or of another insulating material, for example of plastic, however not using the DCB technology. Furthermore, the described process is also generally suitable for the selective surface processing of metal layers or components that for example are to be provided with one or more layers e.g. of metal on only one surface.

In principle it is of course also possible that the processing steps for the selective surface treatment be repeated, i.e. at least two times, namely for example in the embodiments described in the drawings such that in a first phase, the selective surface treatment of the metallizations 3 takes place, as described above, and then in a second phase, in which then two multiple substrates 7 for example are detachably connected by means of the connecting element 12 on their tops in order to seal the latter, the selective surface treatment of the metallizations 4 takes place. Analogous to this, the selective surface treatment is possible in several phases also with other substrates and components.

Furthermore, it was assumed above that the structured metallizations 3 are produced by means of masking and etching technology. It is, of course, also possible to apply these metallizations 3 to the respective insulating layer, e.g. ceramic layer, already in structured form.

### REFERENCE LIST

1 DCB single substrate
2 ceramic layer
3, 4 metallization
3′, 4′ copper foil
5, 6 surface layer
7 multiple substrate
8, 9 metal stud
10, 11 breaking line
12 connecting element
13 vacuum base plate
13′ chamber
14 stud
15 contact surface
16 frame section
17 wraparound seal
18 connection

1. A process for the selective surface treatment of a board-shaped component on at least one of two metallic surfaces, wherein at least two homogenous components are detachably connected with each other on their first surfaces at least in a partial section and sealed from the outside, and that in a treatment phase the selective surface treatment takes place by the connection of non-covered areas of the metallic surfaces.

2. The process as claimed in claim 1, wherein the selective surface treatment takes place by applying at least one metallic covering or one metallic layer.

3. The process as claimed in claim 2, wherein the selective surface treatment takes place by means of chemical and/or electrolytic plating of at least one metallic layer.

4. The process as claimed in claim 1, wherein the sealed and detachable connection of the components takes place in such a manner that each component is completely covered by the connection on one of its surfaces.

5. The process as claimed in claim 1, wherein the components are boards made of metal.

6. The process as claimed in claim 1, wherein the components are printed circuit boards or printed circuit board substrates with at least one insulating layer and one metallization on two outer surfaces.

7. The process as claimed in claim 1, wherein the components are ceramic-metal substrates.

8. The process as claimed in claim 1, wherein the components are DCB substrates, preferably DCB multiple substrates.

9. The process as claimed in claim 1, wherein for the detachable connection of the components a frame-like or plate-like connecting element is used, on which the components are held by means of a bonding and/or adhesive and sealing mass and/or by means of a vacuum.

10. The process as claimed in claim 1, further comprising a plurality of temporally successive phases of a selective treatment, whereby before each phase of the selective surface treatment the components are connected tightly with each other on their surfaces not to be treated.
